(19) United States
(12) Patent Application Publication
(10) Pub. No.: US 2026/0251725 A1
(43) Pub. Date: Aug. 27, 2026

(54) THROUGH-SILICON VIA (TSV) BATCH TESTING

(71) Applicant: Micron Technology, Inc., Boise, ID (US)

(72) Inventors: Yongsuk Choi, Sugar Hill, GA (US); Dae Suk Kim, Sugar Hill, GA (US); Jun Il Moon, Yongin-si (KR)

(21) Appl. No.: 19/533,527

(22) Filed: Feb. 9, 2026

Related U.S. Application Data
(60) Provisional application No. 63/762,849, filed on Feb. 25, 2025.

(51) Int. Cl. G01R 31/52; G01R 31/28; G01R 31/54

(52) U.S. Cl. CPC G01R 31/52; G01R 31/2831; G01R 31/54

(57) ABSTRACT

A configurable resistor can be provided to allow multiple tests of a through-silicon via (TSV) testing for respective connection issues to be performed. The tests can include an open test, which checks for discontinuities or breaks (open defects) in the electrical path of the TSV; a VDDQ short test, which identifies short circuits between the TSV and the VDDQ power rails; and a VSS short test, which identifies short circuits between the TSV and the VSS ground rails.

### PRIORITY INFORMATION

This application claims the benefit of U.S. Provisional Application 63/762,849, filed February 25, 2025, which is incorporated by reference.

### TECHNICAL FIELD

The present disclosure relates generally to semiconductor memory and methods, and more particularly, to apparatuses, systems, and methods for batch testing of TSVs.

### BACKGROUND

Memory devices are typically provided as internal, semiconductor, integrated circuits in computers or other electronic systems. There are many different types of memory including volatile and non-volatile memory. Volatile memory can require power to maintain its data (e.g., host data, error data, etc.) and includes random access memory (RAM), dynamic random access memory (DRAM), static random access memory (SRAM), synchronous dynamic random access memory (SDRAM), and thyristor random access memory (TRAM), among others. Non-volatile memory can provide persistent data by retaining stored data when not powered and can include NAND flash memory, NOR flash memory, ferroelectric random access memory (FeRAM), and resistance variable memory such as phase change random access memory (PCRAM), resistive random access memory (RRAM), and magnetoresistive random access memory (MRAM), such as spin torque transfer random access memory (STT RAM), among others.

Memory devices may be coupled to a host (e.g., a host computing device) to store data, commands, and/or instructions for use by the host while the computer or electronic system is operating. For example, data, commands, and/or instructions can be transferred between the host and the memory device(s) during operation of a computing or other electronic system. A controller may be used to manage the transfer of data, commands, and/or instructions between the host and the memory devices.

### BRIEF DESCRIPTION OF THE DRAWINGS

FIG. 1 is a block diagram of a computing system in accordance with a number of embodiments of the present disclosure.

FIG. 2 is a block diagram of an example stack of memory dies including a testing circuit in accordance with a number of embodiments of the present disclosure.

FIG. 3 is a block diagram of another example stack of memory dies with multiple stacks of TSVs shown in accordance with a number of embodiments of the present disclosure.

FIG. 4 is a flow diagram corresponding to a method 470 for performing a TSV testing in accordance with some embodiments of the present disclosure.

### DETAILED DESCRIPTION

Systems, apparatuses, and methods related to batch testing of through-silicon vias (TSVs) are described. TSV testing is a process used to verify the integrity and functionality of vertical interconnects in three-dimensional integrated circuit (3D IC) architectures, such as high bandwidth memory (HBM) or 3D DRAM architectures. These interconnects enable communication between stacked dies, making them essential for high-density memory and logic devices. TSV testing may involve detecting open connections, identifying short circuits between the TSV and adjacent power rails, and measuring resistance to assess electrical continuity and signal integrity.

Some approaches to TSV testing often perform tests sequentially, where each TSV is tested individually. However, as the testing time increases linearly with the number of TSVs in these approaches, these approaches may be impractical for high-density TSV stacks, especially for devices with thousands of TSVs (e.g., four thousand, eight thousand, etc.).

Further, some approaches may focus on binary open and short tests, which lack the ability to detect subtle defects, such as partial opens or resistance variations. The absence of configurable reference values for resistance measurement further reduces the precision of TSV defect detection. Furthermore, these approaches rely on dedicated test circuits that are not utilized during normal device operation, resulting in inefficient hardware utilization. As TSV stacks grow in complexity, these limitations become more pronounced, posing challenges in both scalability and efficiency.

Aspects of the present disclosure address the above and other challenges by introducing a batch testing methodology capable of batch testing different aspects of multiple TSVs (e.g., Open, VDDQ Short, and VSS Short tests) simultaneously. More particularly, the various embodiments utilize configurable reference values for resistance measurement to improve defect detection, enabling precise identification of subtle defects such as partial opens or resistance variations. This can be done by reusing existing mission-mode receiver circuits for testing purposes, eliminating the need for standalone test circuits and optimizing resource utilization. Furthermore, the present disclosure supports efficient fault localization by selectively enabling control signals, making it possible to quickly identify defective TSVs in large stacks. These advancements make the invention highly scalable and practical for modern high-density TSV applications.

As used herein, the singular forms “a”, “an”, and “the” include singular and plural referents unless the content clearly dictates otherwise. Furthermore, the word “may” is used throughout this application in a permissive sense (i.e., having the potential to, being able to), not in a mandatory sense (i.e., must). The term “include,” and derivations thereof, mean “including, but not limited to.” The term “coupled” means directly or indirectly connected.

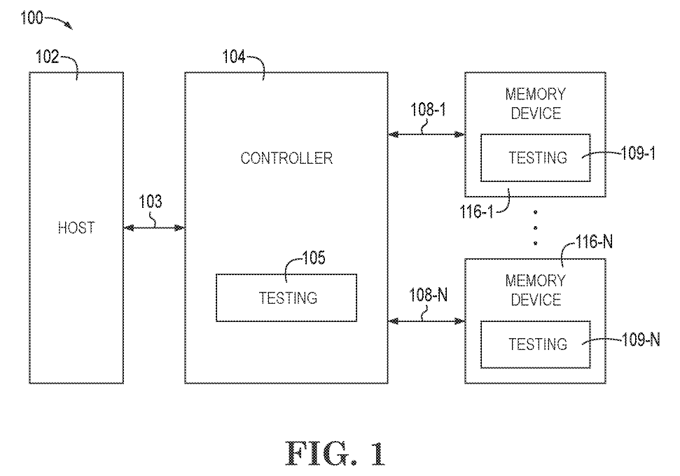

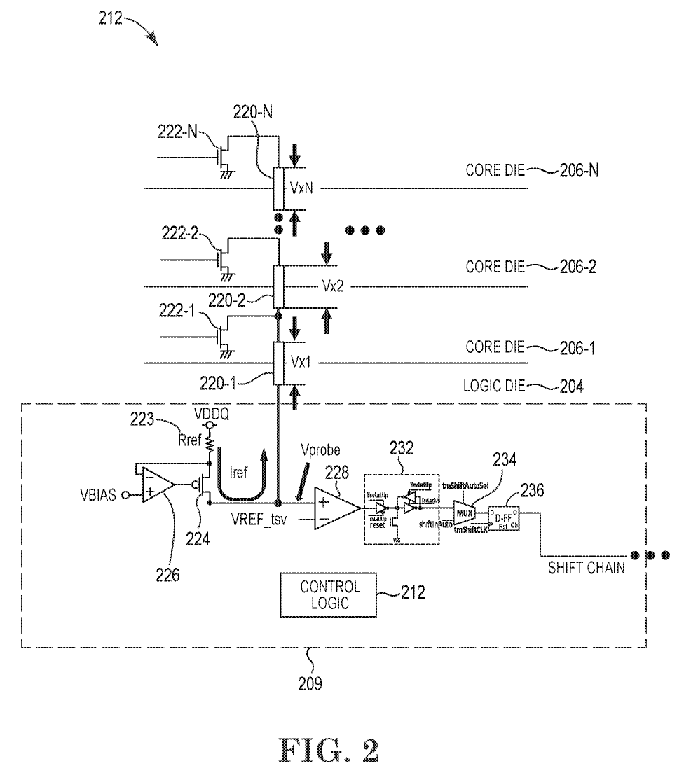

The figures herein follow a numbering convention in which the first digit or digits correspond to the drawing figure number and the remaining digits identify an element or component in the drawing. Similar elements or components between different figures may be identified by the use of similar digits. For example, 109 may reference element “09” in FIG. 1, and a similar element may be referenced as 209 in FIG. 2.

Analogous elements within a Figure may be referenced with a hyphen and extra numeral or letter. See, for example, elements 206-1, …, 206-N in FIG. 2. Such analogous elements may be generally referenced without the hyphen and extra numeral or letter. For example, elements 206-1, …, 206-N may be collectively referenced as 206. As used herein, the designators “N”, “M”, particularly with respect to reference numerals in the drawings, indicates that a number of the particular feature so designated can be included. As will be appreciated, elements shown in the various embodiments herein can be added, exchanged, and/or eliminated so as to provide a number of additional embodiments of the present disclosure. In addition, as will be appreciated, the proportion and the relative scale of the elements provided in the figures are intended to illustrate certain embodiments of the present invention and should not be taken in a limiting sense.

FIG. 1 is a block diagram of a computing system 100 in accordance with a number of embodiments of the present disclosure. The computing system 100 includes a host 102, a controller 106, and memory devices 116-1, …, 116-N, which might also be separately considered an “apparatus.”

The host 102 can include host memory and a central processing unit (not illustrated). The host 102 can be a host system such as a personal laptop computer, a desktop computer, a digital camera, a smart phone, a memory card reader, and/or internet-of-thing enabled device, among various other types of hosts, and can include a memory access device (e.g., a processor and/or processing device). One of ordinary skill in the art will appreciate that “a processor” can intend one or more processors, such as a parallel processing system, a number of coprocessors, etc.

The host 102 can include a system motherboard and/or backplane and can include a number of processing resources (e.g., one or more processors, microprocessors, or some other type of controlling circuitry). The system 100 can include separate integrated circuits or the host 102, the memory controller 104, and the memory devices 116 can be on the same integrated circuit. The system 100 can be, for instance, a server system and/or a high-performance computing (HPC) system and/or a portion thereof. As an example, the system 100 can be, for example, an HBM memory system (e.g., HBM2, HBM3, HBM4, etc.) with the memory devices 116 being stacked on a logic die (which can include controller 104) and interconnected via TSVs, with the stack and host 102 (e.g., processor) being co-located on an interposer coupled to a package substrate.

As illustrated in FIG. 1, the host 102 can be coupled to the controller 104 via an interface 103. The interface 103 can be various types of communication paths, busses, or the like that allows for information to be transferred between the host 102 and the controller 104. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), Small Computer System Interface (SCSI), a double data rate (DDR) memory bus, a dual in-line memory module (DIMM) interface (e.g., DIMM socket interface that supports Double Data Rate (DDR)), Open NAND Flash Interface (ONFI), Double Data Rate (DDR), Low Power Double Data Rate (LPDDR), Compute Express Link (CXL), or any other interface. The physical host interface can be used to transmit data between the host system 102 and the controller 104. The host system 102 can further utilize an NVM Express (NVMe) interface to access components (e.g., memory devices 116) when the memory system (e.g., including the controller 104) is coupled with the host system 102 by the PCIe interface. The physical host interface can provide an interface for passing control, address, data, and other signals between the memory system and the host system 102.

The controller 104 can control performance of memory operations for access commands (e.g., reads and writes) received from the host 102 and directed to one or more memory devices 116. The controller 104 can be coupled to the memory devices 116 via channels 108. The channels 108 can include various types data buses, such as a sixteen-pin data bus and a two-pin data mask inversion (DMI) bus, among other possible buses. In some embodiments, the channels 108 can be part of a physical (PHY) layer. As used herein, the term “PHY layer” generally refers to the physical layer in the Open Systems Interconnection (OSI) model of a computing system. The PHY layer may be the first (e.g., lowest) layer of the OSI model and can be used transfer data over a physical data transmission medium.

The memory device(s) 116 can provide main memory for the computing system 100 or could be used as additional memory or storage throughout the computing system 100. The memory devices 116 can be various/different types of memory devices. For instance, the memory device can include RAM, ROM, DRAM, SDRAM, PCRAM, RRAM, and flash memory, among others. In embodiments in which the memory device 116 includes persistent or non-volatile memory, the memory device 116 can be flash memory devices such as NAND or NOR flash memory devices, for example.

The memory devices 116 can each comprise a number of memory dies (e.g., memory dies 204, 206-1, …, 206-N illustrated in FIG. 2). These memory dies can be coupled (e.g., linked) to one another with the logic die (e.g., the logic die 204 shown in FIG. 2) located on a terminal side. In some embodiments, these linked memory dies can be “stacked” memory dies. Multiple stacked memory dies may form a High Bandwidth Memory (HBM) cube, where each memory dice is connected via through-silicon vias (TSVs) (e.g., TSVs 220-1, …, 220-N of FIG. 2).

The controller 104 can further include a testing component 105. Although not shown in FIG. 1 so as to not obfuscate the drawings, the testing component 105 can include various circuitry to facilitate performance of operations described herein. For example, the testing component 105 can perform those operations associated with testing of TSVs.

As used herein, the term “TSV testing” or similar refers to a procedure for detecting undesired states and/or defects around or within TSVs. For example, TSV testing can include an open test, which checks for discontinuities or breaks (open defects) in the electrical path of the TSV; a VDDQ short test, which identifies short circuits between the TSV and the VDDQ power rails; and a VSS short test, which identifies short circuits between the TSV and the VSS ground rails.

The testing component 105 can cause the memory device 116 to initiate a testing (alternatively referred to as “testing operation”, “testing procedure”, etc.) by issuing commands over a bus (e.g., the channel 108, which can be a CA bus). Upon receiving the command form the testing component 105, the TSV testing can be performed at the memory device 116 via a respective testing circuit 109, which can coordinate testing procedure to be performed/performed on linked memory dies of each memory device 116. For example, the TSV testing can be performed at the memory device 116-1 via the testing circuit 109-N, while the TSV testing can be performed at the memory device 116-N via the testing circuit 109-N. Although embodiments are not so limited, the testing circuit 109 can be implemented and/or located on one of the memory dies, such as at the logic die 204 shown in FIG. 2.

As further described in connection with FIG. 2, TSV testing can be performed on memory dies according to a particular test pattern. In some embodiments, this test pattern may be provided by the testing component 105 of the controller 104 and/or stored in, and provided from, each testing circuit 109.

FIG. 2 is a block diagram of an example stack of memory dies including a testing circuit 209 in accordance with a number of embodiments of the present disclosure. The memory dies can be part of a memory device (e.g., the memory device 116) that is not illustrated in its entirety in FIG. 2 and can further include other portions (including other TSV current paths) that are not illustrated in FIG. 2.

FIG. 2 illustrates a stack of dies including a logic die 204 (alternatively referred to as a “base die”) and core dies 206-1, 206-2, …, 206-N (collectively referred to as core dies 206). Further, as illustrated in FIG. 2, the memory device 216 includes multiple TSVs 220-1, 220-2, ..., 220-N (collectively referred to as TSVs 220), where each TSV 220 electrically connects two respective memory dies. For example, TSV 220-1 connects the logic die 204 to the core die 206-1, TSV 220-2 connects core die 206-1 to core die 206-2, and TSV 220-N connects core dies (e.g., including the core die 206-N). These TSVs collectively form a continuous vertical current path, referred to as a “TSV current path,” which extends across the logic die 204 and core dies 206-1, 206-2, ..., 206-N. As used herein, multiple TSVs (e.g., TSVs 220-1, …, 220-N) that form or are part of the same TSV current path are referred to as a “stack of TSVs” or a “series of TSVs”.

Although embodiments are not so limited, each TSV 220 can be considered as part of the core die it is connected to. For instance, TSV 220-1 may be considered part of core die 206-1, TSV 220-2 may be considered part of core die 206-2, and TSV 220-N may be considered part of core die 206-N.

Each core die 206 also includes a switch (e.g., switches 222-1, 222-2, …, 222-N) that can be coupled to the respective TSV 220. For example, as illustrated in FIG. 2, the core die 206-1 includes a switch 222-1 coupled to the TSV 220-1, the core die 206-2 includes a switch 222-2 coupled to the TSV 220-2, and the core die 206-N includes a switch 222-N coupled to the TSV 220-N. Although embodiments are not so limited, the switch 222 can be an n-channel metal-oxide semiconductor (NMOS) transistor.

Each switch 222 can be enabled or disabled the current path through the respective TSV 220. For example, when the switch 222-1 is turned on (e.g., activated), while the other switches 222 are turned off (e.g., deactivated), this allows current to flow from “VDDQ” (shown in FIG. 2) and through the TSV 220-1, but not through the TSV 220-2. Therefore, switches 222 can function as control points of whether respective TSVs should be included in the TSV current path or not. For example, the switches 222 can be selectively turned on and off to isolate particular TSVs from the current path.

The logic die 204 includes a testing circuit 209, which can be analogous to the testing circuit 109 illustrated in FIG. 1. As illustrated in FIG. 2, the testing circuit 209 includes a switch 224. As shown in FIG. 2, the switch 224 is coupled to the VDDQ power rail (“VDDQ” shown in FIG. 2 and alternatively referred to as a “power supply voltage”). Although embodiments are not so limited, the switch 224 can be a p-channel metal-oxide semiconductor (PMOS) transistor.

The gate of the switch 224 is driven by an output voltage of the comparator 226. The output of the comparator 226 corresponds to a comparison between two input voltages. For example, if the voltage at the inverting input is lower than the voltage at the non-inverting input, the comparator 226 outputs a signal that activates the switch 224. For example, if the voltage at the inverting is higher than or equal to the voltage at the non-inverting input, the comparator 226 outputs a signal that deactivates the PMOS switch.

As shown in FIG. 2, the comparator 226 can receive a voltage “VBIAS” at its non-inverting input. Further, an inverting input of the comparator 226 is further coupled between the switch 224 and a resistor 223 (“Rref” shown in FIG. 2). The voltage “VBIAS” can be applied by the control logic 212 (analogous to the testing circuit 109 shown in FIG. 1) to activate the switch 224. The control logic 212 can control switches of the dies 204 and 206-1, …, 206-N by selectively activating or deactivating the switches 222-1, …, 222-N as well as the switch 224. As an example, the control logic 212 can apply a respective control voltage to each switch 222, 224 (e.g., “VBIAS” to the switch 224) to activate or deactivate the switch 222, 224.

Although not specifically illustrated in FIG. 2, this “VBIAS” block (including the comparator 226) can be shared across the stacks of TSVs, such as stacks of TSVs 342-1, 342-2. Alternatively speaking, the comparator 226 can be controlled by the control logic (by applying a “VBIAS” to the comparator) to collectively and simultaneously (in parallel) activate or deactivate respective switches (e.g., the switch 224) of the stacks of TSVs, which allows the stacks of TSVs to be simultaneously tested.

Once activated, the switch 224 establishes a current path between VDDQ and one or more TSVs (e.g., being tested). This allows current (e.g., the reference current “Iref” shown in FIG. 2) to flow through the selected TSVs. On the other hand, deactivating the switch 224 further disconnects the current path from “VDDQ”.

In a number of embodiments, the reference resistance value (e.g., the value of the resistor 223) can be a particular value that is (e.g., configured to be) sufficient to cause each TSV testing to simultaneously detect different connection issues associated with the current path (formed during the first and second phases). For example, the reference resistance value can be configurable (configured) to a specific level sufficient to simultaneously conduct an open test, a VDDQ short test, and a VSS short test on the TSVs forming a current path, allowing the detection of various issues without performing each test individually. Alternatively speaking, once configured, the same reference resistance value can be utilized to detect the different connection issues.

As shown in FIG. 2, the comparator 228 receives a voltage, “Vprobe”, at its non-inverting input and a reference voltage, “VREF_tsv”, at its inverting input. The voltage “Vprobe” corresponds to the voltage at a node connected to the comparator 228, the switch 224, and the first TSV 220-1. Specifically, “Vprobe” represents the difference between the voltage “VDDQ” and the voltage across one or more TSVs 220 being tested. The comparator 228 compares “Vprobe” to the reference voltage “VREF_tsv,” and the result of this comparison serves as an indication of any undesired states in the TSVs under test. For example, an irregular output from the comparator 228 may signal the presence of undesired states.

As used herein, the term “undesired states” refers to states (e.g., one or more) that may necessitate additional TSV testing (referred to as the “second phase” herein) as indicated by the comparator 228. These undesired states may include, but are not limited to, discontinuities or breaks (open defects) in the electrical path of the tested TSVs, short circuits between the TSV and the VDDQ power rails, short circuits between the TSV and the VSS ground rails (e.g., coupled to one side of each switch 222), or any combination thereof.

An output of the comparator 228 can be provided to a comparator block 232 (e.g., comprising three comparators shown in FIG. 2). The comparator block 232 can be configured to operate in a collective manner with the comparator 228 to generate and/or process a signal indicative of (e.g., capable of indicating) a result of TSV testing performed on the TSVs 220. An output of the comparator 228 and/or the comparator block 232 can be referred to as a “testing result”.

The signal processed from the comparator block 232 can be further provided to a multiplexor 234 (simply referred to as “MUX”). A MUX 234 can be controlled by a control signal (“tmShiftAutoSel” shown in FIG. 2) to output one of two inputs, the signal received from the comparator block 232 or a signal (“shiftInAuto” shown in FIG. 2) that is indicative of (e.g., capable of indicating) a testing result of the other stack of TSVs.

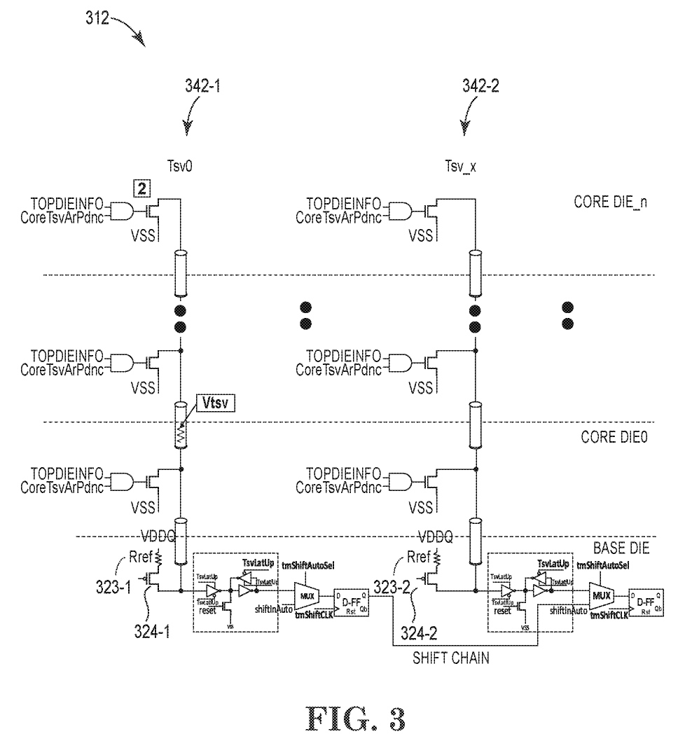

The MUX 234 is further coupled to a flip-flop 236 (e.g., D-Flip-Flop). The flip-flop 236 can be configured to temporarily store and/or outputs the signal provided via the MUX 234, which is to ensure that test results can be propagated systematically to/through the “SHIFT CHAIN” shown in FIG. 2. As further described herein, “SHIFT CHAIN” is configured to (along with the flip-flop 236) allow “parallel testing” to be performed simultaneously over multiple stacks of TSVs. In the testing circuits, each data line (DQ) that is coupled to a TSV 220 in the logic die 204 can be equipped with comparators (e.g., comparators 228 and/or comparators of the comparator block 232) and the data latch 236. This configuration (which includes comparator 228, the comparators within comparator block 232, and/or latches) can be implemented for each data line (DQ) coupled to a respective stack of TSVs (e.g., stacks of TSVs 342-1, 342-2), thereby enabling parallel testing of each data line and independent processing of test result data. Further details of “parallel testing” are described in connection with FIG. 3.

A first phase (alternatively referred to as an initial phase) of the TSV testing can be initiated by activating the switch 224 and the switch 222-N to allow the reference current (“Iref” shown in FIG. 2) to flow through the TSVs 220-1, …, 220-N of the dies 204, 206. For example, the activated switch 224 and 222-N allows the reference current “Iref” to flow through the TSVs 220-1, …, 220-N. In some embodiments, the switch 222-N can be activated substantially simultaneously with or subsequent to the activation of the switch 224. During the first phase, the voltage “Vprobe” can generally correspond to the difference between the voltage “VDDQ” and the voltages over TSVs 220-1, …, 220-N (e.g., VDDQ - Iref*(Rref + Rx1 + Rx2 + … + RxN)).

As used herein, the term “substantially” means that the characteristic need not be absolute, but is close enough so as to achieve the advantages of the characteristic. For example, “substantially simultaneously” is not limited to operations that are performed absolutely simultaneously and can include timings that are intended to be simultaneously but due to manufacturing limitations may not be precisely simultaneously.

If the comparison performed by the comparator 228 does not reveal any undesired states, the TSV testing may proceed without requiring secondary testing (e.g., the “second phase” described herein). If undesired states are indicated as a result of the comparison between the voltage “Vprobe” and the reference voltage “VREF_tsv” at the comparator 228, a second phase (alternatively referred to as a subsequent phase) of the TSV testing can be subsequently initiated. In this phase, the switches 222-1, …, 222-(N-1) are sequentially and selectively activated to identify the specific TSV 220 (e.g., one or more TSVs 220) responsible for causing the undesired states.

For example, during the first iteration of the second phase, the switch 224 and the switch 222-1 can be activated, while the other switches 222 remain deactivated. This configuration allows the reference current, “Iref,” to flow exclusively through TSV 220-1, thereby testing TSV 220-1 individually (as opposed to collectively testing TSVs 220-1, …, 220-N, as was done during the first phase). In this first iteration, the voltage “Vprobe” is compared to the reference voltage “VREF_tsv” to determine whether TSV 220-1 is the source of the undesired states identified during the first phase.

Similarly, during the second iteration of the second phase, the switch 224 and the switch 222-2 can be activated, while the other switches 222 remain deactivated. This configuration allows the reference current, “Iref,” to flow through both TSV 220-1 and TSV 220-2. Similarly, in this second iteration, the voltage “Vprobe” is again compared to the reference voltage “VREF_tsv”. Since TSV 220-1 was individually tested during the first iteration, the second iteration can determine whether TSV 220-2 is responsible for causing the undesired states.

Similarly, during the third iteration of the second phase, the switch 224 and the switch 222-3 can be activated, while the other switches 222 remain deactivated. This configuration allows the reference current, “Iref,” to flow through TSV 220-1, TSV 220-2, and TSV 220-3. Similarly, in this third iteration, the voltage “Vprobe” is again compared to the reference voltage “VREF_tsv”. Since TSV 220-1 and TSV 220-2 each was individually tested during the first iteration and the second iteration, respectively, the third iteration can determine whether TSV 220-2 is responsible for causing the undesired states.

Similarly, during the last (Nth) iteration of the second phase, the switch 224 and the switch 222-3 can be activated, while the other switches 222 remain deactivated. Similarly, in this Nth iteration, the voltage “Vprobe” is again compared to the reference voltage “VREF_tsv”. This configuration allows the reference current, “Iref,” to flow through TSV 220-1, …, TSV 220-N. Since TSV 220-1, …, TSV 220-(N-1) each was individually tested during the first iteration and the second iteration, respectively, the last iteration can determine whether TSV 220-N is responsible for causing “Vprobe” to indicate the undesired states.

In some embodiments, the iterations of the second phase may be performed only as needed to identify a TSV causing “Vprobe” to indicate the undesired states. For example, if the second iteration of the second phase identifies TSV 220-2 as the source of the undesired states, the second phase may conclude without further testing of TSVs 220-3 through 220-N.

FIG. 3 is a block diagram of another example stack of memory dies with multiple stacks of TSVs shown in accordance with a number of embodiments of the present disclosure. A memory device 316 is not illustrated in its entirety in FIG. 3 and can further include other stacks of TSVs that are not illustrated in FIG. 3.

FIG. 3 is generally analogous to FIG. 2 except that FIG. 3 illustrates multiple “stacks” of TSVs that are coupled to one another in parallel. For example, although not specifically illustrated in FIG. 3, each switch 324-1, 324-2 can be respectively coupled to reference resistors 323-1, 323-2 each having a particular value that is sufficient to simultaneously detect different connection issues associated with the current path (formed during the first and second phases). For example, the reference resistance value can be configurable (configured) to a specific level sufficient to simultaneously conduct an open test, a VDDQ short test, and a VSS short test on the TSVs forming a current path, allowing the detection of various issues without performing each test individually. Alternatively speaking, once configured, the same reference resistance value can be utilized to detect the different connection issues.

A first stack of TSVs 342-1 (shown as “Tsv0” in FIG. 3 and alternatively referred to as a series of TSVs 342-1) are coupled to a second series of TSVs 342-2 (shown as “Tsv_x” in FIG. 3 and alternatively referred to as a series of TSVs 342-2) at least via a “SHIFT CHAIN” shown in FIG. 3. For example, as shown in FIG. 3, the “SHIFT CHAIN” is coupled to a flip-flop (“D-FF” shown in FIG. 3, which corresponds to the flip-flop 236) corresponding to the series of TSVs 342-1 and further to a multiplexor (e.g., the multiplexor 234 shown in FIG. 2) corresponding to the series of TSVs 342-2.

While not entirely illustrated in FIG. 3, a number of stacks of TSVs can be coupled to one another in the same manner as the stacks of TSVs 342-1, 342-2 are coupled to one another. As a result, a respective multiplexor corresponding to each stack of TSV can receive a testing result of the other (e.g., adjacent) stack of TSVs. This allows the multiplexors that are coupled (e.g., connected to) one another to alarm of connection issues on any one of stacks of TSVs of the memory device 302 that are indicated by the TSV testing performed on the stacks of TSVs.

As described herein, the switches (e.g., switches 324-1, 324-2) coupled to the number of stacks of TSVs (e.g., stacks of TSVs 342-1, 342-2) can be controlled (e.g., activated or deactivated) by the common “VBIAS” block (including the comparator 226 shown in FIG. 2), which allows collective and simultaneous (in parallel) activation or deactivation respective switches (e.g., the switch 224) of the stacks of TSVs such that the stacks of TSVs can be simultaneously tested.

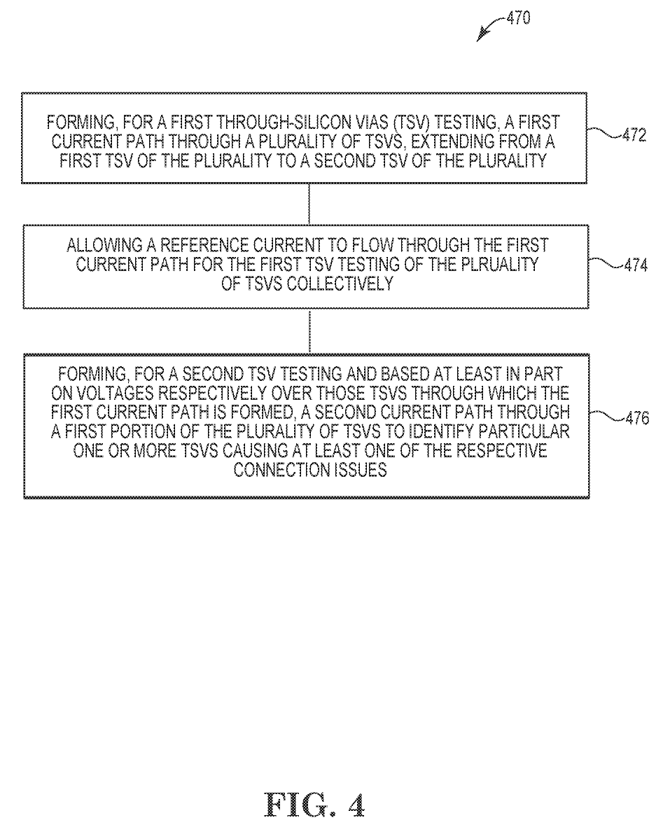

FIG. 4 is a flow diagram corresponding to a method 470 for performing a TSV testing in accordance with some embodiments of the present disclosure. The method 470 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 470 is performed by the testing circuit 109, 209 of FIGS. 1 and 2 and/or the control logic 212. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At 472, a first current path can be formed (for a first through-silicon vias (TSV) testing) through a plurality of TSVs (e.g., TSVs 220-1, …, 220-N shown in FIG. 2), extending from a first TSV (e.g., the TSV 220-1 shown in FIG. 2) of the plurality to a second TSV (e.g., the TSV 220-N shown in FIG. 2) of the plurality. At 474, a reference current (“Iref” shown in FIG. 2) can be allowed to flow through the first current path for the first TSV testing of the plurality of TSVs collectively.

A value of the reference current is configured to cause the first TSV testing to (e.g., simultaneously) detect respective connection issues associated with the first current path, including detecting an open defect, a short circuit in the first current path, or any combination thereof. Alternatively speaking, the first TSV testing can be performed using the same reference current for the multiple tests. In some embodiments, whether the connection issue is revealed (indicated) by the first TSV testing can be determined by comparing at least a sum of the voltages (“Vx1”, “Vx2”, …, “VxN” shown in FIG. 2) respectively over those TSVs through which the first current path is formed to a testing reference voltage (“VREF_tsv” shown in FIG. 2). More particularly, the testing reference voltage can be compared to a total sum of those voltages (a voltage over “Rref” shown in FIG. 2 and voltages (“Vx1”, “Vx2”, …, “VxN” shown in FIG. 2).

At 476, a second current path can be formed (to perform a second TSV testing) through a first portion of the plurality of TSVs (e.g., from the TSVs 220-1 to a TSV located adjacent to the TSV 220-N) to identify particular one or more TSVs causing a connection issue. Whether the second TSV testing is to be performed or not can be determined based at least in part on voltages respectively over those TSVs through which the first current path is formed. For example, the second current path can be formed to perform the second TSV testing responsive to the first TSV testing being indicative of the connection issue. In some embodiments, the second TSV testing may not be (e.g., need not be) performed responsive to the first TSV testing not being indicative of the connection issue.

In some embodiments, the second current path can be formed through the first portion of the plurality of TSVs, extending from the first TSV 220-1 to a third TSV located adjacent to the second TSV 220-N. In this example, the reference current can be allowed to flow through the second current path for the second TSV testing of the first portion of the plurality of TSVs collectively. Continuing with this example, a third current path can be formed through a second portion of the plurality of TSVs, extending from the first TSV 220-1 to a fourth TSV located adjacent to the third TSV, based at least in part of voltages respectively over those TSVs through which the second current path is formed (e.g., responsive to the second TSV testing not revealing the connection issue).

Although specific embodiments have been illustrated and described herein, those of ordinary skill in the art will appreciate that an arrangement calculated to achieve the same results can be substituted for the specific embodiments shown. This disclosure is intended to cover adaptations or variations of one or more embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the one or more embodiments of the present disclosure includes other applications in which the above structures and processes are used. Therefore, the scope of one or more embodiments of the present disclosure should be determined with reference to the appended claims, along with the full range of equivalents to which such claims are entitled.

In the foregoing Detailed Description, some features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. A method, comprising:
forming, for a first through-silicon vias (TSV) testing, a first current path through a plurality of TSVs, extending from a first TSV of the plurality to a second TSV of the plurality;
allowing a reference current to flow through the first current path for the first TSV testing of the plurality of TSVs collectively, wherein a value of the reference current is configured to cause the first TSV testing to simultaneously detect respective connection issues associated with the first current path, including detecting an open defect, a short circuit in the first current path, or any combination thereof; and
forming, for a second TSV testing and based at least in part on voltages respectively over those TSVs through which the first current path is formed, a second current path through a first portion of the plurality of TSVs to identify particular one or more TSVs causing at least one of the respective connection issues.

2. The method of claim 1, further comprising forming the second current path through the first portion of the plurality of TSVs responsive to the first TSV testing being indicative of the connection issues.

3. The method of claim 1, determining that the first TSV testing has revealed the connection issues by comparing at least a sum of the voltages respectively over those TSVs through which the first current path is formed to a testing reference voltage.

4. The method of claim 1, further comprising:
forming the second current path through the first portion of the plurality of TSVs, extending from the first TSV to a third TSV located adjacent to the second TSV; and
allowing the reference current to flow through the second current path for the second TSV testing of the first portion of the plurality of TSVs collectively.

5. The method of claim 4, further comprising forming, for a third TSV testing and based at least in part on voltages respectively over those TSVs through which the second current path is formed, a third current path through a second portion of the plurality of TSVs, extending from the first TSV to a fourth TSV located adjacent to the third TSV.

6. An apparatus, comprising:
a plurality of through-silicon vias (TSVs); and
a control logic configured to:
form, for a first TSV testing, a first current path through the plurality of TSVs, extending from a first TSV of the plurality to a second TSV of the plurality to allow a reference current to flow through the current path to collectively test the plurality of TSVs, wherein a value of the reference current is configured to allow the first TSV to simultaneously detect multiple connection issues associated with the current path, including detecting an open defect, a short circuit in the first current path, or any combination thereof; and
form, for a second TSV testing, a second current path through at least a portion of the plurality of TSVs to identify particular one or more TSVs causing at least one of the connection issues based at least in part on a comparison between a reference voltage and voltages respectively over those TSVs through which the current path is formed.

7. The apparatus of claim 6, further comprising a comparator and a reference resistor through which the reference current flows, wherein:
the reference resistor is further connected to a power supply voltage; and
the first TSV is coupled between the comparator and the reference resistor.

8. The apparatus of claim 7, wherein the comparator is configured to compare a first input voltage corresponding to a testing reference voltage to a second input voltage.

9. The apparatus of claim 8, wherein the second input voltage corresponds to a difference between the power supply voltage and a sum of the voltages respectively over those TSVs and the reference voltage.

10. The apparatus of claim 7, wherein:
the reference resistor is coupled to a switch; and
the control logic is configured to activate or deactivate the switch coupled to the reference resistor to allow or not allow the reference current to flow through the first current path or the second current path.

11. The apparatus of claim 10, wherein the switch corresponds to a p-channel metal-oxide semiconductor (PMOS) transistor.

12. The apparatus of claim 6, wherein:
each TSV of the plurality of TSVs is coupled to a respective switch of a plurality of switches; and
the control logic is configured to selectively activate or deactivate the plurality of switches to form the first current path or the second current path.

13. The apparatus of claim 12, wherein at least one of the plurality of switches corresponds to a n-channel metal-oxide semiconductor (NMOS) transistor.

14. The apparatus of claim 12, wherein the control logic is configured to activate, to form the first current path, a first switch of the plurality of switches coupled to the second TSV, while the other switches of the plurality of switches remain deactivated.

15. The apparatus of claim 12, wherein:
the control logic is configured to activate, to form the second current path, a second switch of the plurality of switches coupled to a third TSV located adjacent to the second TSV, while the other switches of the plurality of switches remain deactivated; and
wherein the second TSV is a terminal TSV among the plurality of TSVs.

16. An apparatus, comprising:
a plurality of first memory dies with each memory die of the plurality of memory dies comprising a respective through-silicon via (TSV) of a plurality of TSVs; and
a second memory die comprising:
a reference resistor coupled to a power supply voltage; and
a control logic, the control logic configured to:
form, for a first TSV testing using the plurality of TSVs, a first current path through the plurality of first memory dies and the second memory die to allow a reference current to flow through the first current path, wherein a value of the reference resistor is configured to allow the first TSV testing to simultaneously detect multiple connection issues associated with the first current path, including detecting an open defect, a short circuit in the first current path, or any combination thereof; and
form, for a second TSV testing using a first portion of the plurality of TSVs and in response to the first TSV testing being indicative of the connection issues, a second current path through a first portion of the plurality of first memory dies and the second memory die to simultaneously detect the multiple connection issues associated with the second current path.

17. The apparatus of claim 16, wherein the second memory die further comprises a comparator, the comparator configured to:
receive a first input voltage corresponding to a testing reference voltage and a second input voltage, wherein:
the second input voltage corresponds to a difference between the power supply voltage and a particular voltage; and
the particular voltage corresponds to a sum of voltages respectively over those TSVs tested a voltage over the reference resistor during the first TSV testing or the second TSV; and
compare the first input voltage to the second input voltage, wherein an output of the comparator is capable of indicating the connection issues.

18. The apparatus of claim 16, wherein:
the plurality of TSVs corresponds to one of a plurality of stacks of TSVs and the reference resistor is one of a plurality of reference resistors respectively coupled to the plurality of stacks of TSVs; and
wherein respective values of the plurality of reference resistors are configured to simultaneously detect multiple connection issues associated with respective current paths of the plurality of stacks of TSVs, including detecting an open defect, a short circuit in the first current path, or any combination thereof.

19. The apparatus of claim 18, wherein:
each reference resistor of the plurality of reference resistors is coupled between the power supply voltage and a respective switch of a plurality of switches, wherein each switch of the plurality of switches is activated to allow a reference current to flow through at least a portion of each of the plurality of stacks of TSVs; and
the control logic is configured to activate the plurality of switches collectively.

20. The apparatus of claim 19, wherein:
the second memory die further comprises a comparator to which the plurality of switches is collectively coupled, wherein the comparator comprises:
a first input coupled between each of the plurality of switches and the respective reference resistor of the plurality of reference resistors; and
a second input configured to receive a bias voltage from the control logic; and
the control logic is configured to apply the bias voltage to the comparator to collectively activate the plurality of switches.
